(19) United States
(12) Patent Application Publication
(10) Pub. No.: US 2011/0001915 A1
(43) Pub. Date: Jan. 6, 2011

(54) DISPLAY PANEL, ARRAY SUBSTRATE, COLOR FILTER SUBSTRATE, AND METHOD FOR PRODUCING DISPLAY PANEL

(76) Inventor: Kenji Kawazoe, Osaka (JP)

Correspondence Address: BIRCH STEWART KOLASCH & BIRCH, PO BOX 747, FALLS CHURCH, VA, 22040-0747, US

(21) Appl. No.: 12/921,041

(22) PCT Filed: Feb. 26, 2009
(86) PCT No.: PCT/JP2009/053515

§ 371 Date: Sep. 3, 2010

(30) Foreign Application Priority Data
Mar. 4, 2008 (JP) 2008-052873

(51) Int. Cl. G02F 1/1339; G02F 1/13; H01L 29/04; G02B 5/22

(52) U.S. Cl. 349/155; 349/187; 257/57; 359/891; 257/E29.003

(57) ABSTRACT

A display panel by which variation in dispersion density of spacers that contribute to definition of a cell gap therebetween is reduced so as to make the cell gap uniform, an array substrate, a color filter substrate, and a method for producing a display panel. The display panel is configured such that one of an array substrate 10 and a color filter substrate 30 that are opposed to each other leaving a given cell gap therebetween includes a concave portion 161, the other substrate includes a convex portion 361 that is opposed to the concave portion, and spacers are interposed between a bottom surface of the concave portion and a top surface of the convex portion.

### BACKGROUND OF THE INVENTION

1. Field of the Invention

The present invention relates to a display panel, an array substrate, a color filter substrate, and a method for producing a display panel. More specifically, the present invention relates to a display panel including spacers arranged to define a cell gap, an array substrate or a color filter substrate that is suitably used in the display panel, and a method for producing a display panel including spacers arranged to define a cell gap.

2. Description of the Related Art

A generally used liquid crystal display panel has a configuration such that a pair of substrates are opposed to each other leaving a minute gap therebetween, and liquid crystals are filled between the pair of substrates. The distance between the pair of substrates, i.e., a cell gap should be maintained at a given uniform size.

In order to maintain the cell gap at the given uniform size, a configuration in which at least one of the pair of substrates is provided with projecting structures, or a configuration in which spherical spacer beads (hereinafter, simply referred to as spacers) are interposed between the pair of substrates is used. In general, in the configuration in which the spacers are interposed, a spacer dispersion liquid prepared by dispersing spacers in a liquid is discharged onto the substrate by ink-jet method so as to locate the spacers at given positions in a given pattern (see Japanese Patent Application Laid-open Publications Nos. 2005-321540, 2006-208728, and 2006-227590).

However, the conventional configuration in which the spacers are located on the substrate by ink-jet method has a problem described below. In this configuration, in order to locate the spacers in a short time, the spacer dispersion liquid is discharged onto one substrate by using a plurality of ink-jet nozzles. However, due to production error of the ink-jet nozzles and other reasons, amounts of the spacers that are discharged from the ink-jet nozzles could differ from one another. In addition, if the spacers are located on a portion projecting on the substrate such as a wiring pattern, some of the spacers depart from the given positions and do not contribute to the definition of the cell gap of the liquid crystal display panel at all.

In other words, in the conventional configuration in which the spacers are located by ink-jet method, dispersion density of the spacers that can contribute to the definition of the cell gap of the liquid crystal display panel varies on one substrate. Such variation generates variation in the size of the cell gap between a region in which many spacers are located and a region in which few spacers are located. Thus, thickness of a liquid crystal layer of the liquid crystal display panel becomes non-uniform, which causes display unevenness.

### SUMMARY OF THE INVENTION

An object of the invention is to overcome the problems described above and to provide a display panel in which variation in dispersion density of spacers that contribute to definition of a cell gap is minimized so as to make the cell gap uniform, thereby preventing occurrence of display unevenness, an array substrate or a color filter that can be suitably used in the display panel, and a method for producing a display panel.

In order to overcome the problems described above, preferred embodiments of the present invention provide a display panel including first and second substrates that are opposed to each other leaving a given cell gap therebetween, the first substrate including a concave portion and the second substrate including a convex portion that is opposed to the concave portion, and spacers that are interposed between a bottom surface of the concave portion and a top surface of the convex portion.

It is preferable that a distance between a region outside the concave portion and a region outside the convex portion is greater than a distance between the bottom surface of the concave portion and the top surface of the convex portion.

It is preferable that the concave portion is provided to at least one of a conductor film and an insulating film that are provided on the first substrate.

It is preferable that the conductor film includes a gate signal line, and the insulating film includes one of a gate insulator and a passivation film.

It is preferable that the convex portion is made from a same material as at least one of an alignment control projection, a light shielding film, and a color layer.

It is preferable that the display panel includes a projecting portion that surrounds the concave portion.

It is preferable that the projecting portion is made from a same material as one of a source signal line and a semiconductor layer.

It is preferable that the concave portion includes a plurality of concave portions arranged at regular intervals and having a same size, and the convex portion includes a plurality of convex portions arranged at regular intervals and having a same size.

It is preferable that the first substrate further includes an auxiliary concave portion that has a depth that is greater than a depth of the concave portion by a given amount, the second substrate further includes a convex portion that is opposed to the auxiliary concave portion, and the spacers are interposed between a bottom surface of the auxiliary concave portion and a top surface of the convex portion.

Preferred embodiments of the present invention also provide an array substrate including a concave portion arranged to accommodate spacers arranged to define a cell gap between the array substrate and an opposed substrate.

It is preferable that the concave portion is provided to at least one of a conductor film and an insulating film.

It is preferable that the conductor film includes a gate signal line, and the insulating film includes one of a gate insulator and a passivation film.

It is preferable that the array substrate includes a projecting portion that surrounds the concave portion.

It is preferable that the projecting portion is made from a same material as one of a source signal line and a semiconductor layer.

It is preferable that the concave portion includes a plurality of concave portions arranged at regular intervals and having a same size.

Preferred embodiments of the present invention also provide a color filter substrate including a convex portion that comes into contact with spacers arranged to define a cell gap between the color filter substrate and an opposed substrate.

It is preferable that the convex portion is made from a same material as at least one of an alignment control projection, a light shielding film, and a color layer.

It is preferable that the convex port ion includes a plurality of convex portions are arranged at regular intervals and having a same size.

Preferred embodiments of the present invention also provide a method for producing a display panel having first and second substrates that are opposed to each other leaving a given cell gap therebetween, the method including the steps of discharging a spacer dispersion liquid prepared by dispersing spacers in a liquid into a concave portion on the first substrate, drying the discharged spacer dispersion liquid, and bonding the second substrate having a convex portion that is opposed to the concave portion to the first substrate.

It is preferable that the spacer dispersion liquid has a property that the spacers gather when the spacer dispersion liquid is dried.

It is preferable that the number of spacers in the spacer dispersion liquid that is discharged into the concave portion in the spacer discharging step is made larger than the number of spacers that can be accommodated in the concave portion.

It is preferable that the first substrate includes a projecting portion that surrounds the concave portion, and the spacer dispersion liquid is discharged within a region surrounded by the projecting portion in the spacer discharging step.

According to the present invention, the concave portion arranged to accommodate the spacers, and the convex portion that comes into contact with the spacers accommodated in the concave portion and is opposed to the concave portion are provided. Therefore, variation in the number of spacers that contribute to the definition of the cell gap of the display panel, i.e., variation in dispersion density is minimized, and the cell gap can be made uniform. Accordingly, a problem such as display unevenness is prevented, which achieves improvement of display quality of an image to be displayed on the display panel.

In addition, the distance between the region outside the concave portion and the region outside the convex portion is greater than the distance between the bottom surface of the concave portion and the top surface of the convex portion. Therefore, the spacers that are not accommodated in the concave portion do not contribute to the definition of the cell gap. In other words, only the spacers accommodated in the concave portion contribute to the definition of the cell gap, and variation in dispersion density of the spacers that contribute to the cell gap can be minimized.

In addition, the concave portion maybe provided to the conductor film on the substrate, and the convex portion may be provided to the light shielding film. Therefore, the number of producing steps of the display device and the substrates constituting the display device is not increased.

The projecting portion surrounds the concave portion. Therefore, diffusion of the spacers that are outside of the concave portion can be prevented. Thus, a problem that translucency is impaired by movement of the spacers to pixel regions of the display panel and contrast and color tone of the display panel are lowered is prevented.

In addition, according to the preferred embodiments of the present invention, the plurality of concave portions are arranged at regular intervals and have the same size, and the plurality of convex portions are arranged at regular intervals and have the same size. Therefore, stress unevenness that is generated between the substrates of the display panel by depressing one of the substrates when bonding the substrate to the other substrate is prevented.

In addition, the first substrate further includes the auxiliary concave portion that has a depth that is greater than a depth of the concave portion by a given amount, the second substrate further includes the concave portion that is opposed to the auxiliary concave portion, and the spacers interposed between the bottom surface of the auxiliary concave portion and the top surface of the convex portion function as auxiliary supporting members that work only when a given size of pressure is applied to the display panel from the outside. Therefore, improvement of mechanical strength of the display panel is achieved.

In addition, the spacers are located in the concave portion by using the spacer dispersion liquid having a property such that the spacers gather when the spacer dispersion liquid is dried. Therefore, when locating the spacers in the concave portion, it is necessary only to spread the spacer dispersion liquid toward the concave portion even if some of the spacers are spread outside the concave portion because the spacers gather into the concave portion. In other words, the spacers can be located inside the concave portion of the substrate with reliability.

### BRIEF DESCRIPTION OF THE DRAWINGS

FIG. 1 is an external oblique view schematically showing a display panel according to a first preferred embodiment of the present invention.

FIGS. 2A and 2B are views for explaining a configuration of an array substrate according to the first preferred embodiment of the present invention. FIG. 2A is a schematic overall view of the array substrate, and FIG. 2B is an enlarged view of a pixel portion (an enlarged view of the portion A in FIG. 2A).

FIG. 3A is a schematic cross-sectional view of a TFT (section B-B in FIG. 2B). FIG. 3B is a schematic cross-sectional view along the center line of a gate signal line in an extending direction (section C-C in FIG. 2B).

FIG. 4A is a schematic overall view of a color filter substrate. FIG. 4B is an enlarged view of the portion D in FIG. 4A.

FIG. 5A is a schematic cross-sectional view of the color filter substrate on a plane passing through color layers (section E-E in FIG. 4B). FIG. 5B is a schematic cross-sectional view of the color filter substrate along a light shielding film between the color layers (section F-F in FIG. 4B).

FIG. 6 is a schematic cross-sectional view of the display panel along the center line of the gate signal line in the extending direction (cross sections of a concave portion and a convex portion).

FIGS. 7A to 7L are schematic cross-sectional views showing the steps of producing the array substrate of the display panel. FIGS. 7A to 7F are schematic cross-sectional views of the TFT. FIGS. 7G to 7L are schematic cross-sectional views of the array substrate along the center line of the gate signal line in the extending direction.

FIGS. 8A to 8J are schematic cross-sectional views showing the steps of producing the color filter substrate. FIGS. 8A to 8E are schematic cross-sectional views of the color filter substrate on a plane passing through the color layers. FIGS. 8F to 8J are schematic cross-sectional views of the color filter substrate along the light shielding film between the color layers.

FIG. 9A is a schematic cross-sectional view of a display panel according to a second preferred embodiment of the present invention. FIG. 9B is a schematic view of the display panel in a case where a given size of pressure is applied to the display panel from the outside.

FIG. 10A is a schematic cross-sectional view of a display panel according to a first modified example of the present invention. FIG. 10B is a schematic cross-sectional view of a display panel according to a second modified example of the present invention.

### DETAILED DESCRIPTION OF PREFERRED EMBODIMENTS

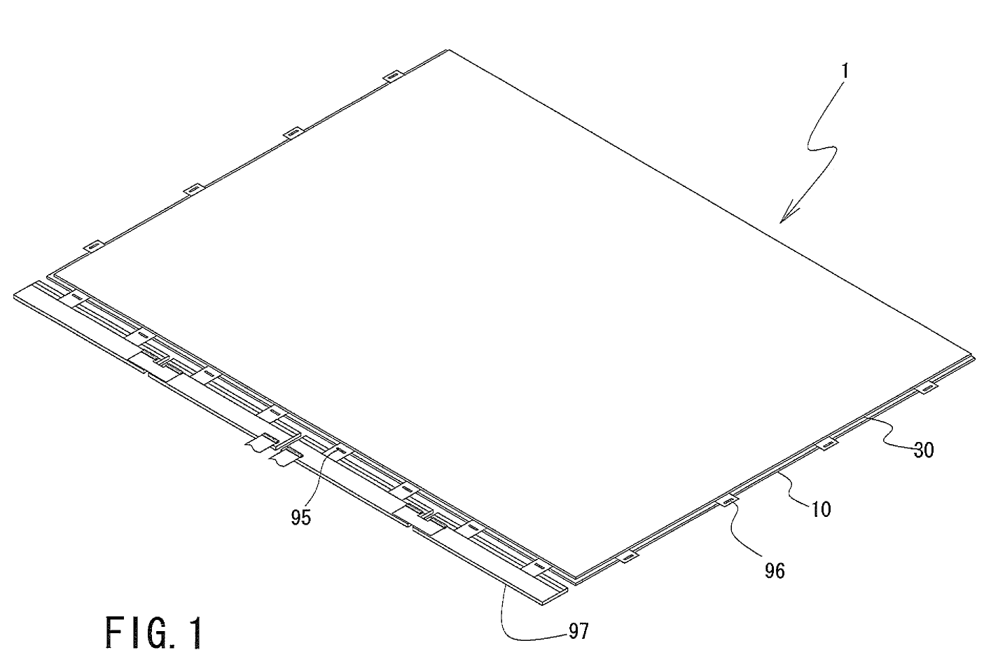

A detailed description of preferred embodiments of the present invention will now be provided with reference to the accompanying drawings. First, a description of a first preferred embodiment of the present invention will be provided. FIG. 1 is an external oblique view schematically showing a display panel 1 according to the first preferred embodiment of the present invention.

As shown in FIG. 1, the display panel 1 according to the first preferred embodiment of the present invention includes an array substrate 10 (hereinafter, sometimes referred to as the array substrate 10 according to the first preferred embodiment of the present invention) and a color filter substrate 30 (hereinafter, sometimes referred to as the color filter substrate 30 according to the first preferred embodiment of the present invention). The array substrate 10 and the color filter substrate 30 are opposed to each other leaving a given cell gap, and liquid crystals are filled between the array substrate 10 and the color filter substrate 30. On the periphery of the display panel 1, source drivers 95 arranged to generate source signals, gate drivers 96 arranged to generate gate signals, a printed wiring board 97 connected to the source drivers 95, and other constituent elements are provided. Hereinafter, detailed descriptions of configurations of the array substrate 10 and the color filter substrate 30 of the display panel 1 will be provided.

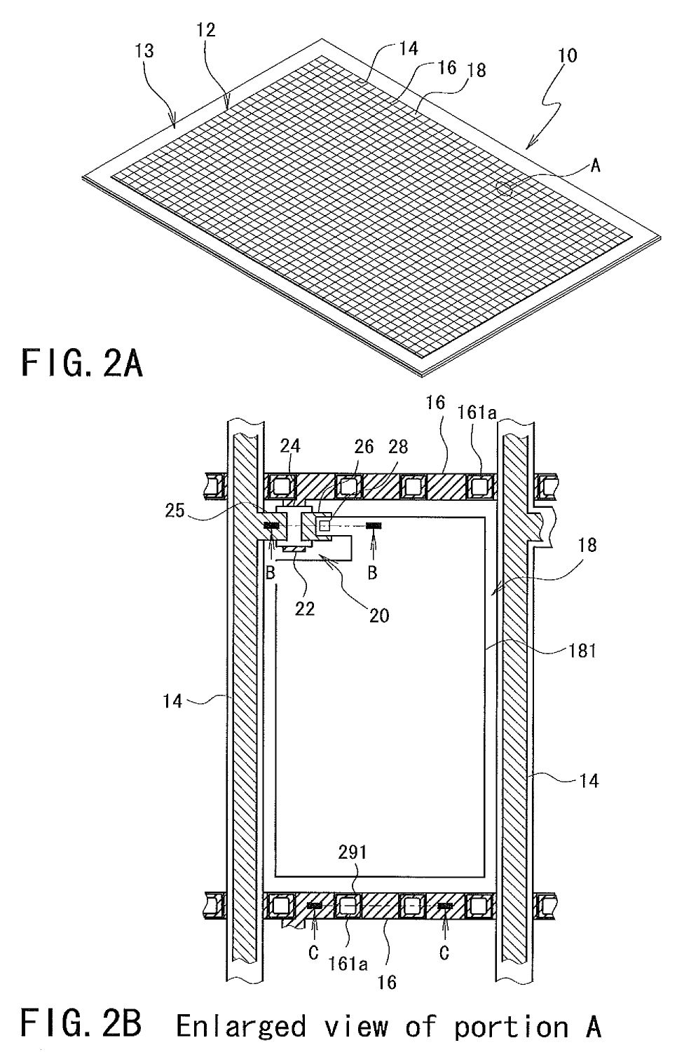

FIGS. 2A and 2B are views for explaining the configuration of the array substrate 10 according to the first preferred embodiment of the present invention. FIG. 2A is a schematic overall view of the array substrate 10, and FIG. 2B is an enlarged view of a pixel portion (an enlarged view of the portion A in FIG. 2A). As shown in FIG. 2A, the array substrate 10 includes an active region 12 and a panel frame region 13 on a glass substrate 90.

In the active region 12, a plurality of source signal lines 14 (in other words, data signal lines, source bus lines) are provided substantially parallel to each other. In addition, a plurality of gate signal lines 16 (in other words, scanning signal lines, gate bus lines) are provided substantially parallel to each other so as to intersect substantially at right angles with the source signal lines 14. The source signal lines 14 and the gate signal lines 16 partition the active region 12 into pixel portions 18 in a matrix arrangement.

As shown in FIG. 2B, the source signal lines 14 and the gate signal lines 16 intersect in such a manner that the source signal lines 14 are positioned above the gate lines 16 at intersecting points, and are electrically insulated. In the regions surrounded by the source signal lines 14 and the gate signal lines 16, i.e., in the pixel portions 18, pixel electrodes 181 (a transparent conductive film) are provided. It should be noted that storage capacitor lines arranged to generate storage capacitor are omitted in order to simplify the descriptions.

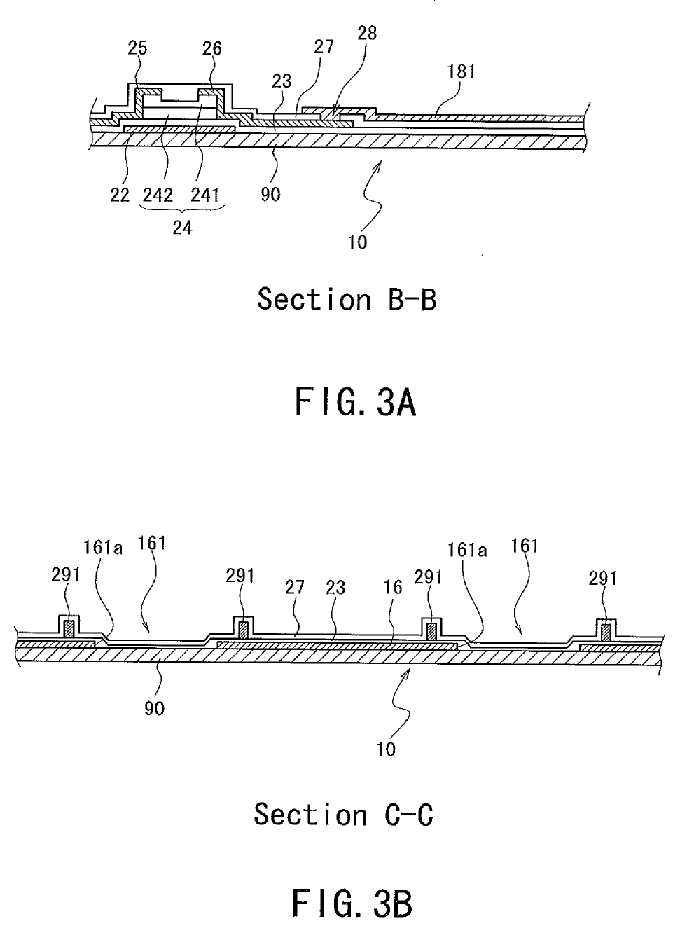

At the intersecting points of the source signal lines 14 and the gate signal lines 16, TFTs (thin film transistors) 20 defining switching elements of the pixel electrodes 181 are provided. FIG. 3A is a schematic cross-sectional view of the TFT 20 (section B-B in FIG. 2B). The TFT 20 is provided by laminating the glass substrate 90 with a gate electrode 22, a gate insulator 23, a semiconductor layer 24 (a first semiconductor layer 241 and a second semiconductor layer 242), a source electrode 25, a drain electrode 26, and a passivation film 27. In addition, a contact hole 28 extends from the surface of the passivation film 27 to the drain electrode 26. Owing to the contact hole 28, the pixel electrode 181 is electrically connected to the drain electrode 26.

The gate signal line 16 includes depressions 161a that provide concave portions 161 arranged to accommodate spherical spacers 92 arranged to define a cell gap between the array substrate 10 and the color filter substrate 30. FIG. 3B is a schematic cross-sectional view (section C-C in FIG. 2B) along the center line of the gate signal line 16 in the extending direction. In the first preferred embodiment of the present invention, the depressions 161a of the gate signal line 16 are covered with the gate insulator 23 and the passivation film 27 so that the concave portions 161 are provided. A cross section of the concave portions 161 on a plane parallel to the array substrate 10 is laterally symmetrical with respect to the center line of the gate signal line 16 in the extending direction. The concave portions 161 are arranged at regular intervals and are equal in size.

The size of the concave portions 161 is determined with reference to the size of the spherical spacers 92 to be accommodated in the concave portions 161 (detailed descriptions will be provided later). The cross section (size) of the concave portions 161 on a plane parallel to the array substrate 10 is such a size that a given number of spherical spacers 92 can be accommodated in the concave portions 161 substantially without interspaces (in a state that the spherical spacers 92 substantially come into contact with each other). The depth of the concave portions 161 is a depth that is smaller than the diameter of the spherical spacers 92 and is configured such that the spherical spacers 92 once located do not easily roll out from the concave portions 161.

The depressions 161a that provide the concave portions 161 are not necessarily provided to the gate signal line 16. For example, the depressions 161a that provide the concave portions 161 may be provided to the gate insulator 23 or the passivation film 27 that is provided on the gate signal line 16.

On the array substrate 10, projecting portions 291 surround the concave portions 161. The height of the projecting portions 291 is a height such that when the array substrate 10 and the color filter substrate 30 are bonded to each other, the top surfaces of the projecting portions 291 do not come into contact with the color filter substrate 30, and that the spherical spacers 92 do not surmount the projecting portions 291 even if the spherical spacers 92 roll (preferably the height of the projecting portions 291 is greater than the diameter of the spherical spacers 92). In the first preferred embodiment of the present invention, the projecting portions 291 are made from the same material as the source signal lines 14 (the source electrodes 25, the drain electrodes 26). However, the present invention is not limited thereto. The projecting portions 291 maybe made from the same material as the semiconductor layer 24 (the first semiconductor layer 241 and the second semiconductor layer 242).

In a region outside the active region 12, i.e., the panel frame region 13, drawing lines arranged to transmit data signals from the outside to the source signal lines 14, drawing lines arranged to transmit gate signals from the outside to the gate signal lines 16, and other given lines are provided (not shown).

Next, a description of the color filter substrate 30 of the display panel according to the first preferred embodiment of the present invention will be provided.

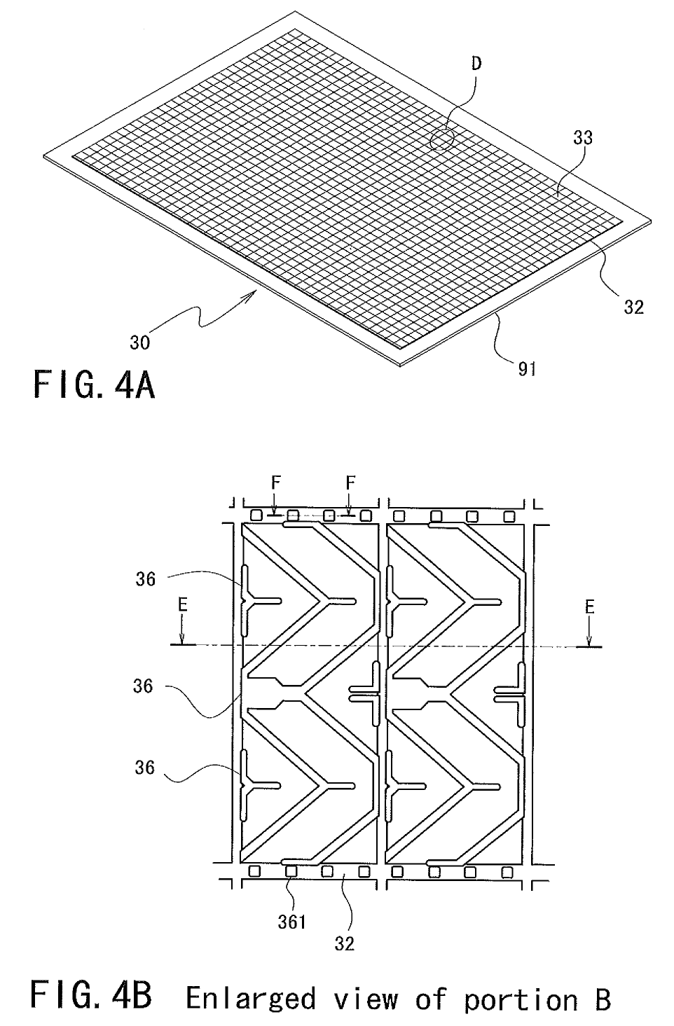

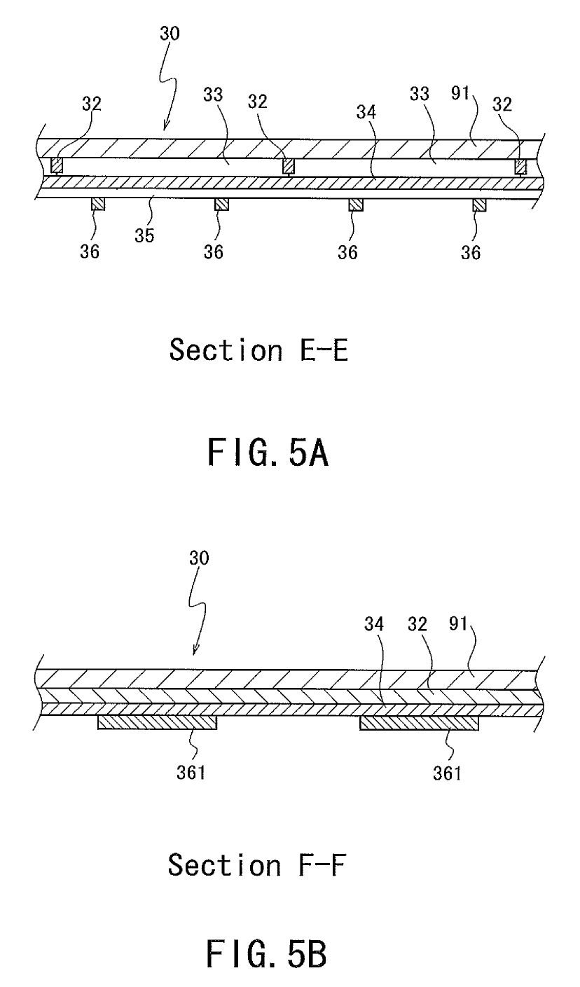

FIGS. 4A to 5B are views for explaining the configuration of the color filter substrate 30. FIG. 4A is a schematic overall view of the color filter substrate 30. FIG. 4B is an enlarged view of the portion D in FIG. 4A. FIG. 5A is a schematic cross-sectional view of the color filter substrate 30 on a plane passing through color layers 33 (section E-E in FIG. 4B). FIG. 5B is a schematic cross-sectional view showing the color filter substrate 30 along a light shielding film 32 between the color layers (section F-F in FIG. 4B).

As shown in FIGS. 4A to 5B, the color filter substrate 30 includes a transparent substrate 91 preferably made from glass, the light shielding film 32 provided on the transparent substrate 91, and the color layers 33 of red, green, and blue within the squares of the light shielding film 32. The squares in which the color layers 33 are provided are arranged in a given order. On the light shielding film 32 and the color layers 33, a protection film 34 is provided, and on the protection film 34, a transparent electrode (common electrode) 35 arranged to apply voltage to a liquid crystal layer is provided. On the transparent electrode (common electrode) 35, alignment control projections 36 are provided.

The light shielding film 32 is arranged to optically separate the color layers 33 and is a so-called black matrix. The light shielding film 32 is preferably made from a resin material containing a black color agent. The color layers 33 are arranged to impart given color properties to light transmitted through pixels and are made from red, green, and blue color resists. The alignment control projections 36 are arranged to control alignment of liquid crystal molecules to be filled between the substrates (impart a pre-tilt angle to liquid crystal molecules with respect to the substrates) in order to improve visual features of the display panel 1 and a response time of liquid crystal molecules. The alignment control projections 36 are preferably made from a resin material, and the shape of the alignment control projections 36 is not particularly limited.

As shown in FIGS. 4B and 5B, convex portions 361 are provided along the light shielding film 32 on the protection film 34. The convex portions 361 are opposed to the concave portions 161 when the color filter substrate 30 and the array substrate 10 are bonded to each other. The cross section (size) of the convex portions 361 on a plane parallel to the color filter substrate 30 is substantially equal to the size of the concave portions 161, and the height of the convex portions 361 is a given height that is determined in accordance with the cell gap and other factors of the display panel 1. A description of the given height will be provided later. In the first preferred embodiment of the present invention, the convex portions 361 are made from the same material as the alignment control projections 36. However, the present invention is not limited thereto. The convex portions 361 may be made from the same material as the light shielding film 32 or the color layers 33.

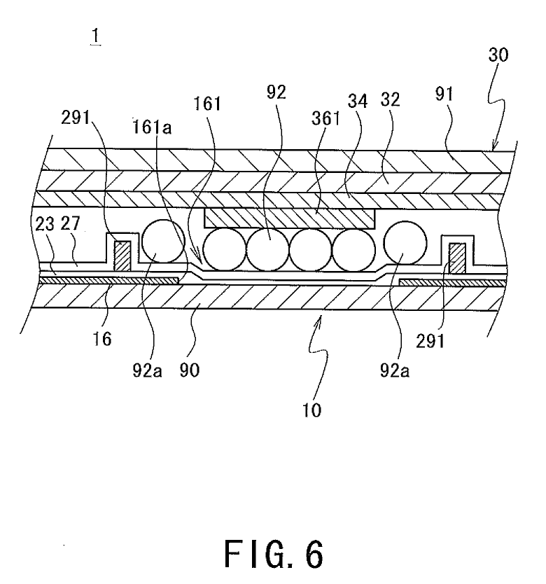

The display panel 1 includes the array substrate 10 and the color filter substrate 30 having the configurations described above. FIG. 6 is a schematic cross-sectional view of the display panel 1 along the center line of the gate signal lines 16 in the extending direction (cross sections of the concave portions 161 and the convex portions 361).

As shown in FIG. 6, the spherical spacers 92 are interposed between the array substrate 10 and the color filter substrate 30. The spherical spacers 92 are accommodated in the concave portions 161 substantially without interspaces (in a state that the spherical spacers 92 are substantially in contact with each other), and are in contact with the convex portions 361 that are opposed to the concave portions 161. To be more specific, the spherical spacers 92 are interposed between the bottom surfaces of the concave portions 161 of the array substrate 10 and the top surfaces of the convex portions 361 of the color filter substrate 30. In other words, the cell gap of the display panel 1 is defined by the depth of the concave portions 161, the height of the convex portions 361, and the diameter of the spherical spacers 92, and accordingly, by adjusting these values, the display panel 1 having an intended cell gap can be obtained.

In the first preferred embodiment of the present invention, the depth of the concave portions 161, the height of the convex portions 361, and the diameter of the spherical spacers 92 are set such that the distance between a region outside the concave portions 161 and a region outside the convex portions 161 is greater than the distance between the bottom surfaces of the concave portions 161 and the top surfaces of the convex portions 361, i.e., the diameter of the spherical spacers 92. Accordingly, spherical spacers 92a that are not accommodated in the concave portions 161 (that are outside of the concave portions 161) do not come into contact with both of the array substrate 10 and the color filter substrate 30.

As described above, the display panel 1 according to the first preferred embodiment of the present invention is configured such that the array substrate 10 includes the concave portions 161 arranged to accommodate the spherical spacers 92, and the color filter substrate 30 includes the convex portions 361 that come into contact with the spherical spacers 92 accommodated in the concave portions 161. Accordingly, variation in the number of spherical spacers 92 that contribute to the definition of the cell gap, which is caused when the spherical spacers 92 are simply spread on the array substrate 10 or the color filter substrate 30, is minimized, by which the cell gap can be made uniform.

The distance between the region outside the concave portions 161 and the region outside the convex portions 361 is greater than the distance between the bottom surfaces of the concave portions 161 and the top surfaces of the convex portions 361. Accordingly, the spherical spacers 92a that are outside of the concave portions 161 do not contribute to the definition of the cell gap. In other words, only the spherical spacers 92 accommodated in the concave portions 161 contribute to the definition of the cell gap, and the spherical spacers 92a that are spread on the other regions do not contribute to the definition of the cell gap. Accordingly, variation in dispersion density of the spherical spacers 92 that contribute to the definition of the cell gap can be minimized.

As described above, the projecting portions 291 surround the concave portions 161. Accordingly, diffusion of the spherical spacers 92a that are outside of the concave portions 161 is prevented. Thus, contrast and color tone of the display panel 1 are prevented from being lowered by movement of the spherical spacers 92 to the pixel regions.

In addition, the concave portions 161 and the convex portions 361 are arranged at regular intervals in the array substrate 10 and the color filter substrate 30 of the display panel 1, the concave portions 161 have a same size, and the convex portions 361 have a same size. Accordingly, stress unevenness that is generated between the substrates of the display panel 1 by depressing one of the substrates when bonding the substrate to the other substrate can be prevented.

Next, a description of a method for producing the display panel 1 according to the first preferred embodiment of the present invention is provided. The method for producing the display panel 1 according to the first preferred embodiment of the present invention includes the step of producing the array substrate 10, the step of producing the color filter substrate 30, and the step of producing a panel (cell). Descriptions of the steps are provided sequentially.

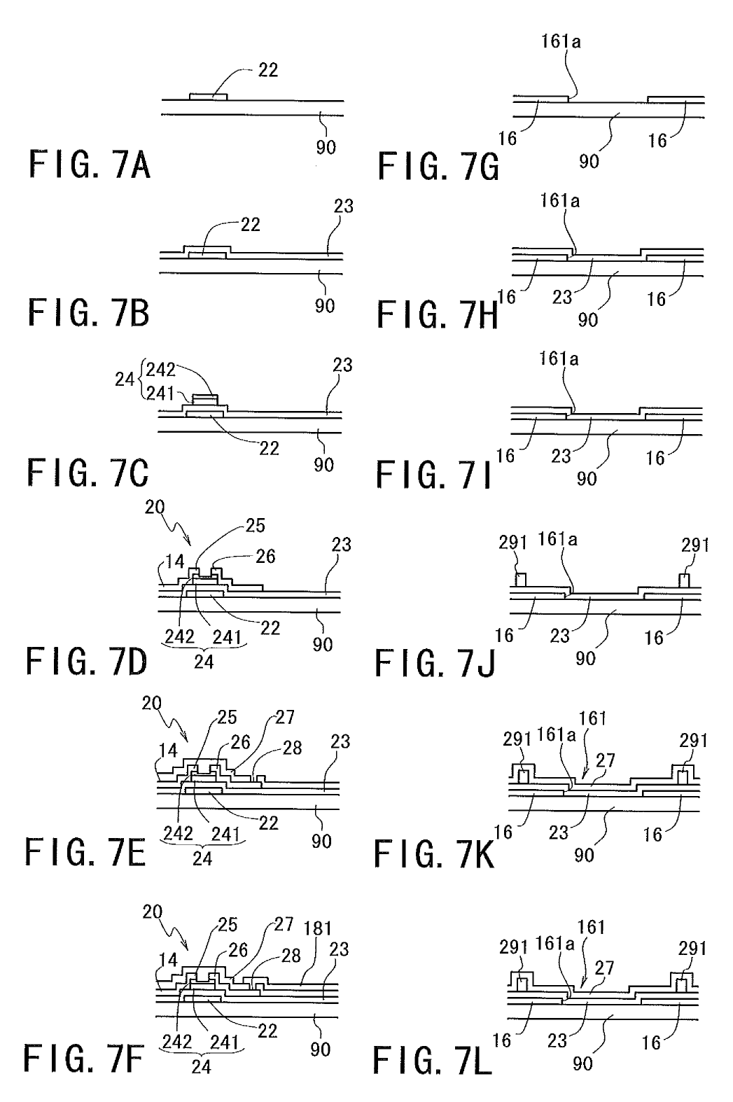

FIGS. 7A to 7L are schematic cross-sectional views showing the steps of producing the array substrate 10 of the display panel 1. FIGS. 7A to 7F are schematic cross-sectional views of the TFT 20. FIGS. 7G to 7L are schematic cross-sectional views of the array substrate 10 along the center line of the gate signal line 16 in the extending direction. Each combination of FIGS. 7A and 7G, FIGS. 7B and 7H, FIGS. 7C and 7I, FIGS. 7D and 7J, FIGS. 7E and 7K, and FIGS. 7F and 7L shows the same step.

The array substrate 10 according to the first preferred embodiment of the present invention is prepared by laminating one of the surfaces of the glass substrate 90 with a conductor film, a semiconductor film, an insulator, and other films in a given order.

The gate signal lines 16, auxiliary capacitance lines (not shown), and the gate electrodes 22 are provided in the active region 12 as shown in FIGS. 7A and 7G. In this step, data drawing lines (not shown) are provided in the panel frame region 13 at the same time. In addition, backup lines (not shown) are provided in this step.

To be specific, a single-layer or multilayer first conductor film preferably made from chromium, tungsten, molybdenum, or aluminum is formed on one of the surfaces of the glass substrate 90. For the formation of the first conductor film, known sputtering method may be used. The thickness of the first conductor film is not particularly limited and may be about 100 nm, for example.

The first conductor film formed as described above is subjected to patterning into patterns of the gate signal lines 16, the auxiliary capacitance lines, the gate electrodes 22, and the data drawing lines, preferably by photolithography. For the patterning of the first conductor film, wet etching may be used. For example, if the first conductor film is made from chromium, wet etching using (NH₄)₂[Ce(NH₃)₆]+HNO₃+H₂O solution may be used. As shown in FIG. 7G, the patterning of the gate signal lines 16 is performed such that a given number of depressions 161a that provide the concave portions 161 are formed at regular intervals along the extending direction of the gate signal lines 16. The shape of the depressions 161a is as described above.

Next, the gate insulator 23 is formed on the glass substrate 90 having passed through the above step as shown in FIGS. 7B and 7H. For the material of the gate insulator 23, SiNx (silicon nitride) having a thickness of about 300 nm is preferably used. Then, the material of the gate insulator 23 is deposited by plasma CVD so as to have a given thickness. By providing the gate insulator 23 as described above, the gate signal lines 16, the auxiliary capacitance lines, the gate electrodes 22, and the data drawing lines are covered with the gate insulator 23 as shown in FIGS. 7B and 7H. The depressions 161a that provide the concave portions 161 on the gate signal lines 16 are also covered with the gate insulator 23.

Then, the semiconductor layer 24 constituted of the first semiconductor layer 241 and the second semiconductor layer 242 is provided at given positions on the gate insulator 23 (positions corresponding to the gate electrodes 22) as shown in FIG. 7C. For the first semiconductor layer 241, amorphous silicon having a thickness of about 100 nm may be used. For the second semiconductor layer 242, n⁺ type amorphous silicon having a thickness of about 20 nm may be used. The second semiconductor layer 242 is also called an ohmic contact layer and is arranged to improve ohmic contact with the source electrode 25 and the drain electrode 26 that are provided in the later steps.

The first semiconductor layer 241 and the second semiconductor layer 242 are provided preferably by plasma CVD and photolithography. First, the materials of the first semiconductor layer 241 and the second semiconductor layer 242 are deposited by plasma CVD. Then, the materials of the first semiconductor layer 241 and the second semiconductor layer 242 are subjected to patterning into given shapes preferably by photolithography. For the patterning, wet etching using HF+HNO₃ solution may be used.

Then, the source signal lines 14, and the source electrodes 25 and the drain electrodes 26 constituting the TFTs 20 are formed in the active region 12 as shown in FIGS. 7D and 7J. At the same time, the projecting portions 291 that are made from the same material as the source signal lines 14 (the source electrodes 25, the drain electrodes 26) are provided so as to surround the depressions 161a (the concave portions 161). The shape of the projecting portions 291 is as described above.

To be more specific, the second conductor film is formed on the glass substrate 90 having passed through the above steps. The second conductor film may be a single layer or multilayer conductor film that is preferably made from titanium, aluminum, chromium, or molybdenum. The method for providing the second conductor film is preferably plasma CVD.

Then, the second conductor film thus formed is subjected to patterning into a given shape preferably by photolithography. Accordingly, the source signal lines 14, and the source electrodes 25 and the drain electrodes 26 constituting the TFTs 20 that are made from the second conductor film are formed in the active region 12. At the same time as the patterning of the second conductor film, patterning of the projecting portions 291 that are provided so as to surround the concave portions 161 into a given shape is performed. In the patterning of the second conductor film, etching is performed at a given depth on the first semiconductor layer 241 and the second semiconductor layer 242 at positions corresponding to the gate electrodes 22 of the TFTs 20.

By performing the above steps, the gate electrodes 22, the TFTs 20 constituted of the sources electrode 25 and the drain electrodes 26 are provided in the active region 12 as shown in FIG. 7D. In addition, the gate signal lines 16 are provided with the depressions 161a that provide the concave portions 161 arranged to accommodate the spherical spacers 92, and the projecting portions 291 surrounding the depressions 161a (the concave portions 161) are provided on the gate signal lines 16 as shown in FIG. 7J.

Then, the passivation film 27 is formed as shown in FIGS. 7E and 7K. To be specific, the passivation film 27 is formed on the glass substrate 90 having passed through the above steps, and patterning of the passivation film 27 is performed. Accordingly, the passivation film 27 having a given shape is obtained. For the passivation film 27, silicon nitride (SiNx) having a thickness of about 400 nm may be used. The method for forming the passivation film 27 is preferably plasma CVD. The method for the patterning of the passivation film 27 is preferably dry etching using SF₆+O₂. The depressions 161a on the gate signal lines 16 are covered with the gate insulator 23 and the passivation film 27 so as to provide the concave portions 161. The shape of the concave portions 161 is as described above.

By the patterning in this step, the contact holes 28 arranged to electrically connect the drain electrodes 26 and the pixel electrodes 181 are formed in the TFTs 20 as shown in FIG. 7E.

Then, the pixel electrodes 181 that are controlled by the TFTs 20 are formed as shown in FIG. 7F. For the material of the pixel electrodes 181, ITO (Indium Tin Oxide) having a thickness of about 150 nm is preferably used.

The method for forming the ITO film is preferably plasma CVD. The pixel electrodes 181 are formed by performing patterning on the ITO film to have a give shape. For the patterning of the pixel electrodes 181, wet etching using HCl+HNO₃+H₂O solution is used.

By the patterning, the pixel electrodes 181 having the given shape are provided in the active region 12 as shown in FIG. 7F. The pixel electrodes 181 are electrically connected to the drain lines through the contact holes 28 on the passivation film 27.

By performing the above steps, the array substrate 10 constituting the display panel 1 according to the first preferred embodiment of the present invention is obtained.

As described above, in the step of producing the array substrate 10, the depressions 161a that provide the concave portions 161 arranged to accommodate the spherical spacers 92 are provided at the same time in the step of forming the gate signal lines 16. Therefore, an additional step of forming the concave portions 161 is not required. In addition, if the patterning of the gate signal lines 16 is performed by photolithography, it is necessary only to change a photomask in accordance with the shape of the concave portions 161, and the number of photomasks required is not increased.

As described above, the depressions 161a that provide the concave portions 161 are not necessarily provided to the gate signal lines 16 and may be provided to the gate insulator 23 or the passivation film 27. Also in the latter case, the depressions 161a are provided at the same time in the step of forming the gate insulator 23 or the passivation film 27, and therefore, an additional step of forming the concave portions 161 is not required.

The projecting portions 291 that are provided so as to surround the concave portions 161 are made from the same material as the source signal lines 14 (the source electrodes 25, the drain electrodes 26). Therefore, the projecting portions 291 can be provided in the same step as the source signal lines 14 (the source electrodes 25, the drain electrodes 26), and an additional step of forming the projecting portions 291 is not required. In addition, if the patterning of the projecting portions 291 is performed by photolithography, it is necessary only to change a photomask in accordance with the shape of the projecting portions 291, and the number of photomasks required is not increased.

As described above, the projecting portions 291 are not necessarily made from the same material as the source signal lines 14 (the source electrodes 25, the drain electrodes 26) and may be made from the same material as the semiconductor layer 24 (the first semiconductor 241 and the second semiconductor 242). In the latter case, if the projecting portions 291 are formed in the same step as the step of forming the semiconductor layer 24, an increase in the number of steps is not required.

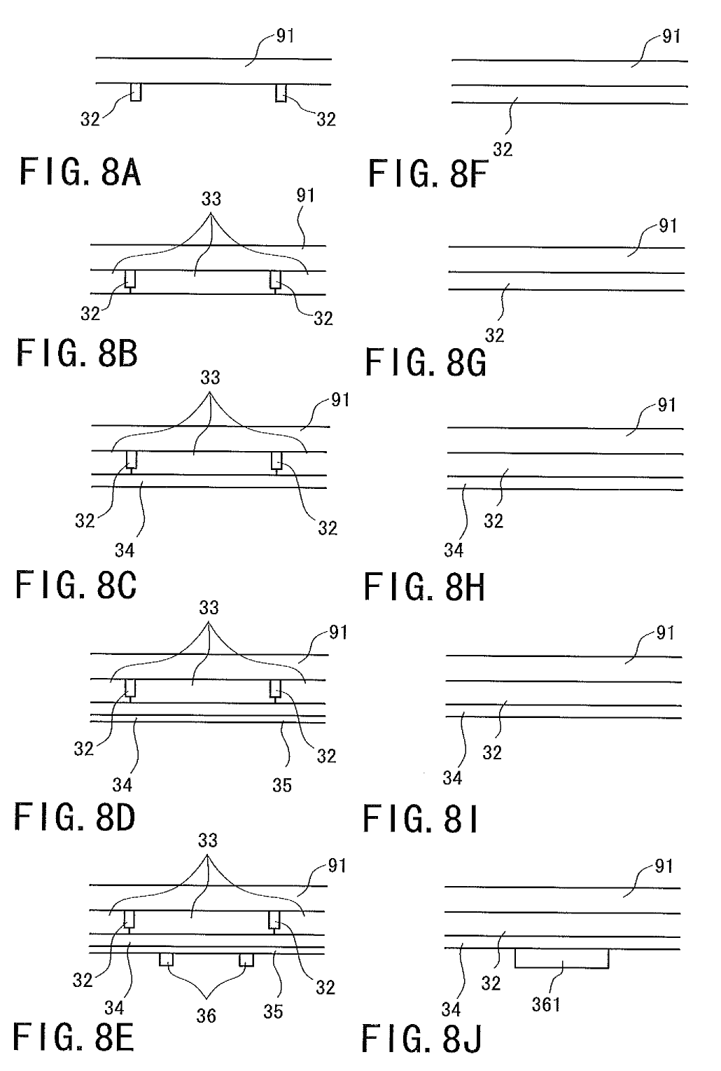

Next, a description of the step of producing the color filter substrate 30 according to the preferred embodiments of the present invention will be provided. FIGS. 8A to 8J are schematic cross-sectional views showing the steps of producing the color filter substrate 30. FIGS. 8A to 8E are schematic cross-sectional views of the color filter substrate 30 on a plane passing through the color layers 33. FIGS. 8F to 8J are schematic cross-sectional views of the color filter substrate 30 along the light shielding film 32 between the color layers 33. Each combination of FIGS. 8A and 8F, FIGS. 8B and 8G, FIGS. 8C and 8H, FIGS. 8D and 81, and FIGS. 8E and 8J shows the same step.

The step of producing the color filter substrate 30 includes the light shielding film (black matrix) forming step, the color layer forming step, the protection film forming step, the transparent electrode (common electrode) forming step, and the alignment control projection forming step.

Details of the light shielding film forming step in the case of using a resin BM process are as described below. First, a BM resist (a photosensitive resin material containing a black color agent) is applied on the transparent substrate 91 as shown in FIGS. 8A and 8F. Then, the applied BM resist is made to have a given pattern preferably by photolithography. Thus, the light shielding film 32 of the given pattern is obtained.

In the color layer forming step, the red, green, and blue color layers 33 for color display are provided as shown in FIG. 8B. In the case of using color resist method, the color layer forming step is performed as described below. First, a color resist (a solution prepared by dispersing a pigment of a given color in photosensitive material) is applied on the transparent substrate 91 on which the light shielding film 32 is formed. Then, the color resist applied is made to have a given pattern preferably by photolithography. This step is performed for each of red, green, and blue colors. Thus, the color layers 33 of the colors are obtained.

The method used in the light shielding film forming step is not limited to resin BM method, and various known methods such as chromium BM method and overlap method may be used. The method used in the color layer forming step is not limited to color resist method, and various known methods such as printing method, dyeing method, electrodeposition method, transfer method, and photo-etching method may be used. In addition, back-face exposure method in which the color layers 33 are firstly formed and the light shielding film 32 is secondly formed may be used.

Then, in the protection film forming step, the protection film 34 is formed on the light shielding film 32 and the color layers 33 as shown in FIGS. 8C and 8H. For example, a method for applying a protection film material on the transparent substrate 91 having passed through the above steps with the use of a spin coater (overcoating method), or a method for forming the protection film 34 of a given pattern by printing or photolithography (patterning method) may be used. For the protection material, an acrylate resin or an epoxy resin may be used.

Then, in the transparent electrode (common electrode) forming step, the transparent electrode (common electrode) 35 is formed on the protection film 34 as shown in FIG. 8D. In the case of using masking method, the transparent electrode (common electrode) 35 is formed by placing a mask on the transparent substrate 91 having passed through the above steps and depositing ITO (Indium Tin Oxide) preferably by sputtering.

Then, in the alignment control projection forming step, the alignment control projections 36 are formed as shown in FIGS. 8E and 8J. The alignment control projections 36 are formed preferably by photolithography. The photosensitive material is applied on the transparent substrate 91 having passed through the above steps. The applied photosensitive material is subjected to exposure using a photomask to be formed into a given pattern. Then, unnecessary portions are removed in the subsequent development step, and the photosensitive material of a given pattern is left. As a result, the alignment control projections 36 of the given pattern are formed.

At the same time as the formation of the alignment control projections 36, the convex portions 361 are formed. To be specific, the convex portions 361 are made from the same photosensitive material as the alignment control projections 36, and with the use of a photomask on which patterns of the alignment control projections 36 and the convex portions 361 are prepared, patterning of the convex portions 361 is performed at the same time as the patterning of the alignment control projections 36. The convex portions 361 are opposed to the concave portions 161 of the array substrate 10 when the color filter substrate 30 and the array substrate 10 are bonded in the panel (cell) producing step to be described later. The shape of the projecting portions 361 is as described above.

Through the steps described above, the color filter substrate 30 is produced.

As described above, in the step of producing the color filter substrate 30, the convex portions 361 that come into contact with the spherical spacers 92 are provided at the same time in the alignment control projection forming step. Therefore, an additional step of forming the convex portions 361 is not required. In addition, if the patterning of the alignment control projections 36 is performed by photolithography, it is necessary only to change a photomask in accordance with the shape of the convex portions 361, and the number of photomasks required is not increased.

As described above, the convex portions 361 are not necessarily made from the same material as the alignment control projections 36 and may be made from the same material as the light shielding film 32 or the color layers 33. In the latter case, if the convex portions 361 are formed in the same step as the light shielding film forming step or the color layer forming step, the number of steps is not increased.

Next, a description of the step of producing the panel (cell) in which the array substrate 10 and the color filter substrate 30 that are produced in the above steps are assembled.

On the array substrate 10 and the color filter substrate 30 that are obtained by the above steps, alignment films are formed as described below.

First, alignment materials are applied on the array substrate 10 and the color filter substrate 30 with the use of an alignment material coating device. The alignment materials are a solution of substances defining a material of an alignment film. For the alignment material coating device, conventionally used devices such as a cylinder printing press and an ink-jet printing press may be used. The applied alignment material is heated and sintered preferably with the use of an alignment film sintering device.

Then, alignment treatment is performed on the sintered alignment films. For the alignment treatment, various known treatment methods such as a method for making minute scratches on the alignment films with the use of a rubbing roll and photo-alignment treatment of adjusting a surface property of the alignment films by irradiating light energy such as ultraviolet light onto the alignment films may be used.

Then, a sealing material is applied on one of the array substrate 10 and the color filter substrate 30 preferably with the use of a seal patterning device.

Then, the spherical spacers 92 arranged to keep the cell gap uniform at a given value are spread on the array substrate 10. Details are provided below.

First, the spreading of the spherical spacers 92 is performed with the use of a spacer application device by ink-jet method. To be specific, a spacer dispersion liquid prepared by dispersing the spherical spacers 92 in the given liquid is spread (discharged) on the array substrate 10 by ink-jet method. The spacer dispersion liquid used here has such a property that the spherical spacers 92 gather when discharged droplets are dried. Examples of the spacer dispersion liquid having such a property include L265EX0034KRC made by SEKISUI CHEMICAL CO., LTD. (L265: the type of a liquid (solvent), EX0034KRC: the type of spherical spacers).

The spacer dispersion liquid is discharged by ink-jet method into the concave portions 161 that are previously formed on the array substrate 10 (a spacer discharging step). Then, the spacer dispersion liquid that is discharged into the concave portions 161 is dried so as to remove liquid (a drying step).

In the preferred embodiment of the present invention, the spacer dispersion liquid used has such a property that the dispersed spherical spacers 92 gather when the spacer dispersion liquid is dried. Therefore, only by making the number of spherical spacers 92 contained in the droplets discharged onto one concave portion 161 more than the number of spherical spacers 92 that can be accommodated in the concave portions 161, even if some of the spherical spacers 92 are applied outside the concave portions 161, the spherical spacers 92 can be reliably accommodated without shortage in the concave portions 161. As described above, the concave portions 161 are equal in size, and accordingly, the number of spherical spacers 92 accommodated in each of the concave portions 161 can be made equal.

In addition, the projecting portions 291 are provided so as to surround the concave portions 161. Therefore, only by discharging the spacer dispersion liquid into the regions surrounded by the projecting portions 291, the spherical spacers 92 can be reliably accommodated in the concave portions 161 by a gathering property of the liquid. In addition, the projecting portions 291 prevent the spherical spacers 92 that are outside of the concave portions 161 from being freely diffused, which prevents contrast and color tone of the display panel 1 from being lowered by movement of the spherical spacers 92 to the pixel regions.

Then, the array substrate 10 and the color filter substrate 30 are bonded to each other under a reduced-pressure atmosphere (a substrate bonding step), and liquid crystals are filled between the array substrate 10 and the color filter substrate 30. Alternatively, liquid crystals maybe infused between the array substrate 10 and the color filter substrate 30 after solidifying the sealing material.

After performing the above steps, a lighting inspection is finally performed, and accordingly, the display panel 1 according to the preferred embodiment of the present invention is obtained.

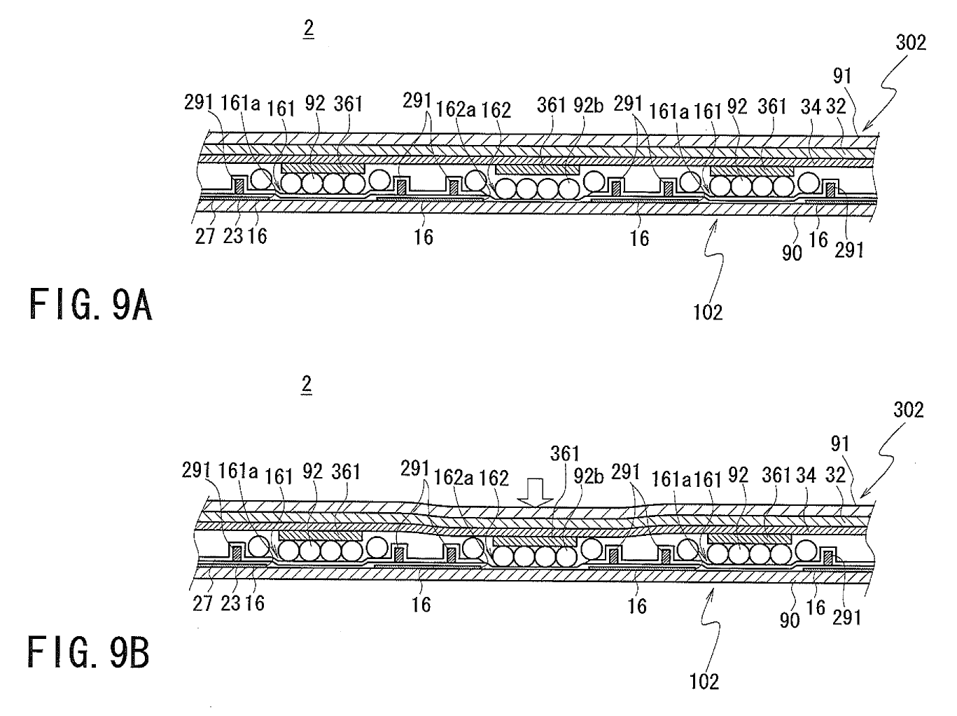

Next, a description of a second preferred embodiment of the present invention is provided. FIG. 9A is a schematic cross-sectional view of a display panel 2 according to the second preferred embodiment of the present invention. It should be noted that in the following description, elements common to the display panel 1 according to the first preferred embodiment of the present invention are assigned the same numerals, and some of the descriptions are omitted.

The display panel 2 includes an array substrate 102 (hereinafter, sometimes referred to as the array substrate 102 according to the second preferred embodiment of the present invention) and a color filter substrate 302 (hereinafter, sometimes referred to as the color filter substrate 302 according to the second preferred embodiment of the present invention). The array substrate 102 and the color filter substrate 302 are opposed to each other leaving a given cell gap, and liquid crystals are filled between the array substrate 102 and the color filter substrate 302.

As shown in FIG. 9A, the array substrate 102 according to the second preferred embodiment of the present invention is configured such that the gate signal lines 16 include second depressions 162a that provide auxiliary concave portions 162 between the depressions 161a that provide the concave portions 161 (hereinafter, sometimes referred to as the first depressions 161a). In other words, the concave portions 161 and the auxiliary concave portions 162 are alternately arranged along the gate signal lines 16 of the array substrate 102. The cross section (size) of the auxiliary concave portions 162 on a plane parallel to the array substrate 102 is configured such that a given number of spherical spacers 92 can be accommodated in the auxiliary concave portions 162 substantially without interspaces (in a state that the spherical spacers 92 substantially come into contact with each other).

The depth of the auxiliary concave portions 162 is greater than the depth of the concave portions 161, while the depth of the first depressions 161a and the depth of the second depressions 162a are equal. To be specific, the concave portions 161 are provided by covering the first depressions 161a with the gate insulator 23 and the passivation film 27, while the second depressions 162a that provide the auxiliary concave portions 162 are provided by removing the passivation film 27 and are covered only with the gate insulator 23. Accordingly, the depth of the auxiliary concave portions 162 is greater than the depth of the concave portions 161 by the thickness of the passivation film 27.

The configuration described above is presented only as an example. The depth of the auxiliary concave portions 162 may be made greater than the depth of the concave portions 161 by the thickness of the gate insulator 23 by making the second depressions 162a covered only with the passivation film 27. In addition, the difference between the depth of the concave portions 161 and the depth of the auxiliary concave portions 162 may be provided by making the depth of the first depressions 161a and the depth of the second depressions 162a different instead of partly removing the gate insulator 23 and the passivation film 27. In addition, the second depressions 162a that provide the auxiliary concave portions 162 may be provided not to the gate signal lines 16 but to the gate insulator 23 or the passivation film 27. In other words, it is essential only that the depth of the auxiliary concave portions 162 that are formed in any one of the gate signal lines 16, the gate insulator 23, and the passivation film 27 be greater than the depth of the concave portions 161.

The method for forming the second depressions 162a that provide the auxiliary concave portions 162 according to the second preferred embodiment of the present invention is the same as the method for forming the first depressions 161a that provide the concave portions 161 according to the first preferred embodiment of the present invention. The removal of the passivation film 27 that is applied on the bottom surfaces of the second depressions 162a is preferably performed in the patterning step of the passivation film 27 (the step of forming the contact hole 28) in order not to increase the number of production steps.

The convex portions 361 are formed on the protection film 34 in the color filter substrate 302 according to the second preferred embodiment of the present invention as shown in FIG. 9A. The shape of the convex portions 361 according to the second preferred embodiment of the present invention is the same as the shape of the convex portions 361 according to the first preferred embodiment of the present invention. The convex portions 361 are positioned so as to be opposed not only to the concave portions 161 but also to the auxiliary concave portions 162 when the color filter substrate 30 and the array substrate 10 are bonded to each other.

The method for forming the convex portions 361 that are positioned so as to be opposed to the auxiliary concave portions 162 is the same as the method for forming the concave portions 161 according to the first preferred embodiment of the present invention.

The spherical spacers 92 arranged to define the cell gap are interposed not only between the concave portions 161 and the convex portions 361 but also between the auxiliary concave portions 162 and the convex portions 361 that are positioned so as to be opposed to the auxiliary concave portions 162 (in FIGS. 9A and 9B, the spherical spacers that are accommodated in the auxiliary concave portions 162 are assigned 92b). The method for locating (spreading) the spherical spacers 92b in the auxiliary concave portions 162 may be ink-jet method as with the case of the method for locating (spreading) the spherical spacers 92b in the concave portions 161.

According to the display panel 2 having the configuration described above, the following action and effect are provided in addition to the above-described action and effect achieved by the first preferred embodiment of the present invention. To be specific, the depth of the auxiliary concave portions 162 is greater than the depth of the concave portions 161, and therefore, the spherical spacers 92b accommodated in the auxiliary concave portions 162 are positioned leaving a given space (according to the second preferred embodiment of the present invention, the given space is the thickness of the passivation film 27) from at least one of the top surfaces of the convex portions 361 and the bottom surfaces of the auxiliary concave portions 162. In other words, in a normal state, the spherical spacers 92b do not contribute to the definition of the cell gap of the display panel 2. However, when a given size of pressure is applied to the display panel 2 from the outside, the substrate (the array substrate 102 or the color filter substrate 302) that is warped is supported by the spherical spacers 92b accommodated in the auxiliary concave portions 162 as shown in FIG. 9B, and damage to the substrate is efficiently prevented. According to the second preferred embodiment of the present invention, the spherical spacers 92b accommodated in the auxiliary concave portions 162 function as supporting members that work only when an external force is applied to the display panel 2, by which improvement of mechanical strength of the display panel 2 is achieved.

It should be noted that the number and shape of the auxiliary concave portions 162 have been presented only as examples. Because the auxiliary concave portions 162 are arranged to improve mechanical strength of the display panel 2 in an auxiliary manner, the number and size of the auxiliary concave portions 162 maybe increased or decreased as necessary. In addition, if the projecting portions 291 are provided so as to surround the auxiliary concave portions 162, diffusion of the spherical spacers 92 that are outside of the auxiliary concave portions 162 can be prevented.

While preferred embodiments of the present invention have been described above, it is to be understood that variations and modifications will be apparent to those skilled in the art without departing from the scope and spirit of the present invention.

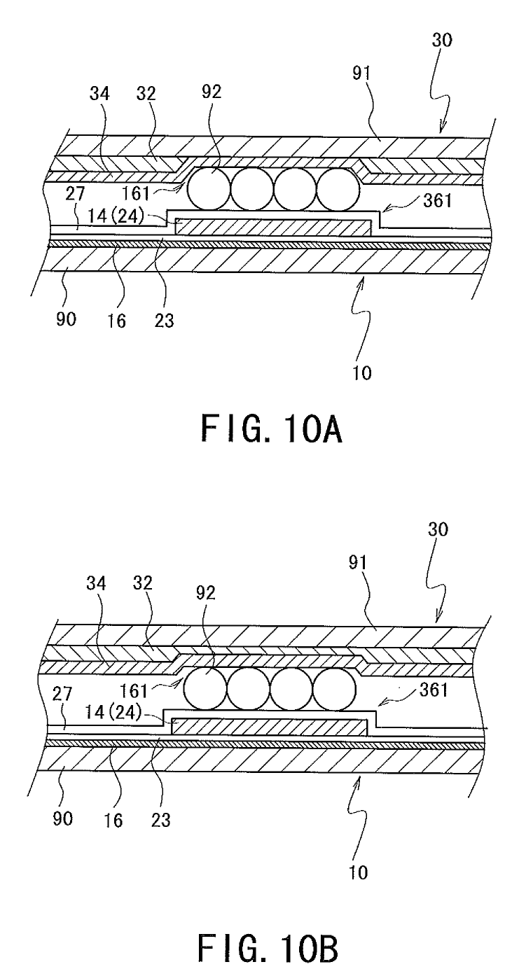

In the preferred embodiments of the present invention, the concave portions 161 are provided to the array substrate 10, and the convex portions 361 are provided to the color filter substrate 30. However, the concave portions 161 may be provided to the color filter substrate 30, and the convex portions 361 may be provided to the convex portions 361. For example, as shown in FIG. 10A, a portion of the light shielding film 32 of the color filter substrate 30 is removed so as to provide the concave portions 161, and the concave portions 361 are provided to the source signal lines 14 (the semiconductor layer 24) or the passivation film 27 (a first modified example of the present invention).

In this case, in case a light shielding property is lowered by removing a portion of the light shielding film 32 and contrast of the display panel is lowered, patterning is performed such that the light shielding film 32 is removed not completely and a portion of the light shielding film 32 is left in the thickness direction as shown in FIG. 10B (patterning is performed by so-called half tone exposure). As a result, the concave portions 161 are provided to the light shielding film 32 while the light shielding property of the light shielding film 32 is maintained (a second modified example of the present invention).

The shape of the spacers arranged to define the cell gap is not limited to the spherical shape. The steps constituting the step of producing the display panel may be modified as appropriate without departing from the scope and spirit of the present invention.

1. A display panel comprising:
first and second substrates that are opposed to each other leaving a given cell gap therebetween, the first substrate comprising a concave portion and the second substrate comprising a convex portion that is opposed to the concave portion; and
spacers that are interposed between a bottom surface of the concave portion and a top surface of the convex portion.

2. The display panel according to claim 1, wherein a distance between a region outside the concave portion and a region outside the convex portion is greater than a distance between the bottom surface of the concave portion and the top surface of the convex portion.

3. The display panel according to claim 1, wherein the concave portion is formed in at least one of a conductor film and an insulating film that are formed on the first substrate.

4. The display panel according to claim 3, wherein the conductor film comprises a gate signal line.

5. The display panel according to claim 3, the insulating film comprises one of a gate insulator and a passivation film.

6. The display panel according to claim 1, wherein the convex portion is made from a same material as at least one of an alignment control projection, a light shielding film, and a color layer.

7. The display panel according to claim 1, further comprising a projecting portion that surrounds the concave portion.

8. The display panel according to claim 7, wherein the projecting portion is made from a same material as one of a source signal line and a semiconductor layer.

9. The display panel according to claim 1, wherein the concave portion comprises a plurality of concave portions that are arranged at regular intervals and have a same size, and
the convex portion comprises a plurality of convex portions that are arranged at regular intervals and have a same size,

10. The display panel according to claim 1, wherein
the first substrate further comprises an auxiliary concave portion that has a depth that is greater than a depth of the concave portion by a given amount,
the second substrate further comprises a convex portion that is opposed to the auxiliary concave portion, and
the spacers are interposed between a bottom surface of the auxiliary concave portion and a top surface of the convex portion.

11. An array substrate comprising a concave portion arranged to accommodate spacers arranged to define a cell gap between the array substrate and an opposed substrate.

12. The array substrate according to claim 11, wherein the concave portion is formed in at least one of a conductor film and an insulating film.

13. The array substrate according to claim 12, wherein the conductor film comprises a gate signal line.

14. The array substrate according to claim 12, wherein the insulating film comprises one of a gate insulator and a passivation film

15. The array substrate according to claim 11, further comprising a projecting portion that surrounds the concave portion.

16. The array substrate according to claim 15, wherein the projecting portion is made from a same material as one of a source signal line and a semiconductor layer.

17. The array substrate according to claim 11, wherein the concave portion comprises a plurality of concave portions that are arranged at regular intervals and have a same size.

18. A color filter substrate comprising a convex portion that comes into contact with spacers arranged to define a cell gap between the color filter substrate and an opposed substrate.

19. The color filter substrate according to claim 18, wherein the convex portion is made from a same material as at least one of an alignment control projection, a light shielding film, and a color layer.

20. The color filter substrate according to claim 18, wherein the convex portion comprises a plurality of convex portions that are arranged at regular intervals and have a same size.

21. A method for producing a display panel having first and second substrates that are opposed to each other leaving a given cell gap therebetween, the method comprising the steps of:
discharging a spacer dispersion liquid prepared by dispersing spacers in a liquid into a concave portion of the first substrate;
drying the discharged spacer dispersion liquid; and
bonding the second substrate having a convex portion that is opposed to the concave portion to the first substrate.

22. The method for producing the display panel according to claim 21, wherein the spacer dispersion liquid has a property that the spacers gather when the spacer dispersion liquid is dried.

23. The method for producing the display panel according to claim 21, wherein the number of spacers included in the spacer dispersion liquid that is discharged into the concave portion in the spacer discharging step is greater than the number of spacers that can be accommodated in the concave portion.

24. The method for producing the display panel according to claim 23, wherein the first substrate comprises a projecting portion that surrounds the concave portion, and the spacer dispersion liquid is discharged within a region surrounded by the projecting portion in the spacer discharging step.
